(19) United States
(12) Patent Application Publication
(10) Pub. No.: US 2025/0011924 A1
(43) Pub. Date: Jan. 9, 2025

(54) MULTILAYERED SILICON NITRIDE FILM

(71) Applicant: VERSUM MATERIALS US, LLC, TEMPE, AZ (US)

(72) Inventors: SE-WON LEE, NAMYANGJU-SI (KR); MOO-SUNG KIM, SUNGNAM-SI (KR); CHANG-WON LEE, SEOUL (KR); XINJIAN LEI, VISTA, CA (US)

(21) Appl. No.: 18/709,806

(22) PCT Filed: Nov. 10, 2022
(86) PCT No.: PCT/US2022/079666

§ 371 Date: May 13, 2024

Related U.S. Application Data
(60) Provisional application No. 63/279,624, filed on Nov. 15, 2021.

(51) Int. Cl. C23C 16/34; C23C 16/44; C23C 16/455

(52) U.S. Cl. CPC C23C 16/345; C23C 16/4408; C23C 16/45536; C23C 16/45553

(57) ABSTRACT

A method for depositing a multi-layered silicon nitride film using a combination of deposition methods includes the steps of placing the substrate into a first reactor and depositing on at least a portion of a surface of a substrate a first silicon nitride film, a second silicon nitride film, and a third silicon nitride film, which together form the multi-layered silicon nitride film, in a sequence of deposition methods alternating between (i) either plasma enhanced atomic layered deposition (PEALD) or plasma enhanced cyclic chemical vapor deposition (PECCVD), and (ii) PECVD as described herein and using at least one silicon precursor compound comprising at least three Si—N bonds and at least three SiH₃ groups represented by formulae A to C described herein.

### CROSS-REFERENCE TO RELATED APPLICATION

This application for patent claims priority to U.S. Provisional Patent Application No. 63/279,623 filed on Nov. 15, 2021, which is incorporated herein, in its entirety.

### BACKGROUND OF THE INVENTION

Silicon nitride is often used as an insulator, and passivation/gas barrier in manufacturing integrated circuits or display devices to electrically isolate different structures or as an etch mask in bulk micromachining. As a passivation layer for microchips, it is superior to silicon dioxide as it is a significantly better diffusion barrier against water molecules and sodium ions, two major sources of corrosion and instability in microelectronics. It is also used as a dielectric between polysilicon layers in capacitors in analog chips.

The deposition of conformal, stoichiometric and non-stoichiometric silicon nitride films at low temperature, e.g., temperatures of about 500° C. or less or about 400° C. or less, which meet one or more criteria to be considered a high quality film, has been a long-standing industry challenge. There are several applications in the semiconductor field such as advanced patterning and spacers which require high quality films. A silicon nitride film is considered a “high quality” film if it has a density of 2.0 grams per cubic centimeter (g/cc) or greater and/or a low wet etch rate (as measured in dilute hydrofluoric acid (HF)) as compared to other silicon nitride films. In these or other embodiments, the refractive index for the silicon nitride film should be 1.8 or greater.

Bang, S. H., et al., “Effects of radio frequency power and gas ratio on barrier properties of SiOₓN_{y} films deposited by inductively coupled plasma chemical vapor deposition.” Thin Solid Films 669: 108-113 (2019) discloses SiOₓN_{y} barrier films that were deposited at a low temperature of ˜23° C. using inductively coupled plasma chemical vapor deposition (ICP-CVD) and in which almost spherical nanoparticles, each of which was isolated without aggregation, were observed. Such a near spherical nanoparticle without aggregation produced highly dense films with enhanced barrier property. However, heavily aggregated nanoparticles produced very porous films with deteriorated barrier property.

Cho, S.-K., et al., “Structural and gas barrier properties of hydrogenated silicon nitride thin films prepared by roll-to-roll microwave plasma-enhanced chemical vapor deposition.” Vacuum 188: 110167 (2021) discloses hydrogenated amorphous silicon nitride films (a-SiNx:H) as barrier layers to prevent the diffusion of water vapor and other gases into electronic devices. The films fabricated under SiH₄-rich conditions (R<2.75) were oxidized during storage in air to produce silicon oxynitride (SiOₓN_{y}), whose properties differed from those of silicon nitride (SiNₓ). It was found that gas barrier properties were affected by both the film and the Si—H bond densities. The compressive and tensile stresses of the SiNₓ:H films depended on the values of R, with excellent mechanic stability and moisture barrier properties having been obtained for R=2.75-3.00.

U.S. Pat. No. 8,592,328B discloses methods of making silicon nitride (SiN) films. One aspect relates to depositing chlorine (Cl)-free conformal SiN films. In some embodiments, the SiN films are Cl-free and carbon (C)-free. Another aspect relates to methods of tuning the stress and/or wet etch rate of conformal SiN films. Another aspect relates to low-temperature methods of depositing high quality conformal SiN films. In some embodiments, the methods involve using trisilylamine (TSA) as a silicon-containing precursor.

Jang, W., et al., “Temperature dependence of silicon nitride deposited by remote plasma atomic layer deposition,” Physica Status Solidi (A) Applications and Materials Science 211: 2166 (2014) discloses the characteristics of silicon nitride thin films deposited by remote plasma atomic layer deposition (RPALD) using trisilyamine (TSA) and ammonia (NH₃) plasma at low temperatures. SiNₓ thin films deposited at 250-350° C. were focused on for analyses. All of the SiNₓ films were nearly stoichiometric, regardless of the deposition temperature. As the deposition temperature increased, the RI increased, while the hydrogen content decreased. The defect density also changed at higher deposition temperatures; as the deposition temperature increased, all of the trap densities increased because of the low-hydrogen content in the SiNₓ thin films. The characteristics of the SiNₓ thin film deposited by RPALD could be controlled to adjust the defect density for charge trap flash memory applications by changing the deposition temperature.

U.S. Pat. Nos. 8,129,291B, 8,173,554B, and 8,415,259 B disclose methods of forming dielectric films having Si—N bonds on a semiconductor substrate by plasma enhanced atomic layer deposition (PEALD). The methods include introducing a nitrogen- and hydrogen-containing reactive gas and a rare gas into a reaction space inside which the semiconductor substrate is placed; introducing a hydrogen-containing silicon precursor in pulses of less than 1.0-second duration into the reaction space wherein the reactive gas and the rare gas are introduced; exiting a plasma in pulses of less than 1.0-second duration immediately after the silicon precursor is shut off; and maintaining the reactive gas and the rare gas as a purge of less than 2.0-second duration.

Lee, W.-J. et al., “Novel plasma enhanced chemical vapor deposition of highly conformal SiN films and their barrier properties,” Journal of Vacuum Science & Technology B, Nanotechnology and Microelectronics: Materials, Processing, Measurement, and Phenomena 36(2): 022201 (2018) disclose a plasma-enhanced chemical vapor deposition technique to fabricate highly conformal silicon nitride (SiN) films and study their barrier properties. TSA was used as the main precursor and was introduced into the reaction chamber in 0.3-s pulses while the plasma was excited. The deposited SiN film exhibited good conformality (91%) and an aspect ratio of ˜4.2 (a width of 70 nm and a depth of 300 nm). The film growth rate was 2.0 Å/cycle. The k-value and leakage current were 7.1-6.66 and lower than 1.0×10-8 A/cm², respectively, at a 1 MV charge (8.5×10-10-3.5×10-8 A/cm²) in the temperature range of 200-400° C. The wet etch rates of the SiN deposition at 200 and 400° C. were 32.1 and 11.1 nm/min, respectively. The wet etch rate of the films was evaluated in a dilute hydrogen fluoride (HF) solution (H₂O:HF=100:1). The 5.0-nm thick SiN films deposited at 200 and 400° C. exhibited excellent abilities to prevent moisture from entering. By modifying the supply method of the Si precursor, the step coverage improved to the plasma enhanced atomic layer deposition level and the moisture barrier property was maintained even at thicknesses of less than 10 nm.

US 20170088684 discloses a gas barrier laminated body with excellent gas barrier property and flex resistance. The gas barrier laminated body comprises a base unit having a substrate and a reforming promotion laver, and a gas barrier layer formed on the reforming promotion layer side of the substrate unit. The gas barrier laminated body has <30 GPa of an elastic modulus of the reforming promotion layer, and ≤51.0 g/(m2·day) of a moisture vapor transmission rate at a substrate unit temp. of 40° C. and a relative humidity of 90%. The gas barrier layer is formed by carrying out a reforming process on the surface of a layer containing a polysilazane compound formed on the reforming promotion layer side of the substrate unit.

Yun, S.-J., et al., “Water vapor transmission rate property of SiNₓ thin films prepared by low temperature (<100° C.) linear plasma enhanced chemical vapor deposition.” Vacuum 148: 33-40 (2018) discloses an inline system equipped with a linear PECVD source available at low temperatures for the thin film encapsulation of flexible org. light emitting diode displays. This inline system can be used for coating on a moving substrate, which can increase productivity better than a cluster system with the typical PECVD source and produces SiNₓ films with excellent water vapor barrier properties.

U.S. Pat. No. 10,316,407B discloses compositions and methods using the same for forming a silicon-containing film or material such as without limitation a silicon oxide, silicon nitride, silicon oxynitride, a carbon-doped silicon nitride, or a carbon-doped silicon oxide film using a single deposition process such as plasma enhanced atomic layer deposition (PEALD) or plasma enhanced cyclic chemical vapor deposition (PECCVD).

There is a need in the art to provide a thin, gas barrier silicon nitride material. Specifically, there is a need for a low temperature (e.g., processing temperature of about 500° C. or less, preferably 300° C. or less, more preferably 200° C. or less, most preferably 100° C. or less) method for depositing a conformal, high quality, silicon nitride film wherein the film has one or more of the following characteristics: a reflective index of 1.8 or higher, a low wet etch rate of 1 Å/s or less (as measured in dilute hydrofluoric acid (HF)), water vapor transmission rate (WVTR) value of 5.0×10⁻⁵ g/m²·day or less, 5.0×10⁻⁴ g/m²·day or less, or 5.0×10⁻³ g/m²·day, and combinations thereof compared to other silicon nitride films using other deposition methods or precursors.

### BRIEF SUMMARY OF THE INVENTION

Described herein are methods for forming stoichiometric or non-stoichiometric multilayered silicon nitride films, for example multi-layered silicon nitride as a gas barrier in semiconductor devices.
According to an exemplary embodiment a method for depositing a multi-layered silicon nitride film employs a combination of deposition methods and includes depositing on at least a portion of a surface of a substrate at least a first silicon nitride film, a second silicon nitride film, and a third silicon nitride film, which together form the multi-layered silicon nitride film, in a sequence of deposition methods alternating between (1) either plasma enhanced atomic layered deposition (PEALD) or plasma enhanced cyclic chemical vapor deposition (PECCVD), and (2) plasma enhanced chemical vapor deposition (PECVD) wherein the PEALD or PECCVD deposition method (1) comprises the following steps a to e, which are repeated until a desired thickness of silicon nitride is obtained:
   a. placing the substrate into a first reactor;
   b. introducing into the reactor at least one silicon precursor compound comprising at least three Si—N bonds and at least three SiH₃ groups represented by Formulae A to C:

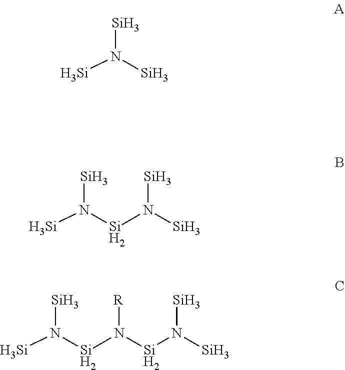

wherein R is independently selected from a hydrogen, a linear C₁ to C₁₀ alkyl group; a branched C₃ to C₁₀ alkyl group; a linear or branched C₃ to C₁₂ alkenyl group; a linear or branched C₃ to C₁₂ alkenyl group; a linear or branched C₃ to C₁₂ alkynyl group; a C₄ to C₁₀ cyclic alkyl group; and a C₆ to C₁₀ aryl group under conditions sufficient to react on at least a portion of the surface to provide a chemisorbed layer;
c. purging the reactor with a purge gas;
d. introducing a first plasma containing source into the reactor to react with at least a portion of the chemisorbed layer and provide at least one reactive site wherein the plasma is generated at a power density ranging from about 0.01 to about 1.5 W/cm²; and
e. optionally purging the reactor with an inert gas;
   and wherein the PECVD deposition method (2) comprises the following steps f to g:
f. placing the substrate into a second reactor; and
g. introducing into the reactor an at least one silicon precursor represented by the structures A to C and a second plasma containing source to form silicon nitride, wherein the plasma is generated at a power density ranging from about 0.01 to about 1.5 W/cm².

### DETAILED DESCRIPTION OF THE INVENTION

The deposition of conformal, stoichiometric and non-stoichiometric silicon nitride films at low temperatures, e.g., temperatures of 500° C. or less or 400° C. or less, or 200° C. or less, or 100° C. or less which meet one or more criteria to be considered a high quality film, has been a long-standing industry challenge. Throughout the description, the term “silicon nitride” as used herein refers to a film comprising silicon and nitrogen selected from the group consisting of stoichiometric or non-stoichiometric silicon nitride and mixtures thereof. A silicon nitride film is considered a “high quality” film if it has one or more of the following characteristics: a density of 2.0 grams per cubic centimeter (g/cc) or greater, a low wet etch rate of 1 Å/s or less (as measured in dilute hydrofluoric acid (HF)), and combinations thereof. In these or other embodiments, the refractive index for the silicon nitride film should be 1.8 or higher.

Throughout the description, the term “alkyl” denotes a linear or branched functional group having from 1 to 10 carbon atoms. Exemplary linear alkyl groups include, but are not limited to, methyl, ethyl, n-propyl, n-butyl, n-pentyl, and n-hexyl groups. Exemplary branched alkyl groups include, but are not limited to, iso-propyl, iso-butyl, sec-butyl, tert-butyl, iso-pentyl, sec-pentyl, tert-pentyl, iso-hexyl, sec-hexyl, tert-hexyl, and neo-hexyl. In certain embodiments, the alkyl group may have one or more functional groups attached thereto such as, but not limited to, an alkoxy group, a dialkylamino group or combinations thereof, attached thereto. In other embodiments, the alkyl group does not have one or more functional groups attached thereto. The alkyl group may be saturated or, alternatively, unsaturated.

Throughout the description, the term “cyclic alkyl” denotes a cyclic functional group having from 3 to 10 carbon atoms. Exemplary cyclic alkyl groups include, but are not limited to, cyclobutyl, cyclopentyl, cyclohexyl, and cyclooctyl groups.

Throughout the description, the term “alkenyl group” denotes a group which has one or more carbon-carbon double bonds and has from 2 to 10 or from 2 to 6 carbon atoms.

Throughout the description, the term “dialkylamino” group, “alkylamino” group, or “organoamino” group denotes a group which has two alkyl groups bonded to a nitrogen atom or one alkyl bonded to a nitrogen atom and has from 1 to 10 or from 2 to 6 or from 2 to 4 carbon atoms. Examples include but not limited to HNMe, HNBu^{t}, NMe₂, NMeEt, NEt₂, and NPrⁱ₂.

Throughout the description, the term “aryl” denotes an aromatic cyclic functional group having from 4 to 10 carbon atoms, from 5 to 10 carbon atoms, or from 6 to 10 carbon atoms. Exemplary aryl groups include, but are not limited to, phenyl, 1-phenylethyl (Ph(Me)CH—), 1-phenyl-1-methyl-ethyl (Ph(Me)₂C—), benzyl, chlorobenzyl, tolyl, o-xylyl, 1,2,3-triazolyl, pyrrrolyl, and furanyl.

Throughout the description, the term “hetero-atom functional groups” refers a linear or branched C₁ to C₂₀ hydrocarbon, cyclic C₆ to C₂₀ hydrocarbon having at least on hetero-atom selected from the group consisting oxygen, nitrogen, fluorine, chlorine, and sulfur. Exemplary hetero-atom functional group s include, but are not limited to, alkoxy, organoamino, cyano, thio, silyl, ether, keto, ester, or halogenated groups or combinations thereof.

Throughout the description, the term “water vapor transmission rate (WVTR)” refers a rate at which water molecules permeate through a barrier layer with a unit of g/m² per day (g/m²·day)

Throughout the description, the term “multi-layered silicon nitride film” refers three or more layered silicon nitride deposited by alternating between (1) either plasma enhanced atomic layered deposition (PEALD) or plasma enhanced cyclic chemical vapor deposition (PECCVD), and (2) PECVD.

In one embodiment the disclosed and claimed subject matter relates to a method to deposit multi-layered silicon nitride via combination of plasma enhanced atomic layer deposition (PEALD) or plasma enhanced cyclic chemical vapor deposition (PECCVD) and plasma enhanced chemical vapor deposition (PECVD) employing one or more of the following silicon precursors:

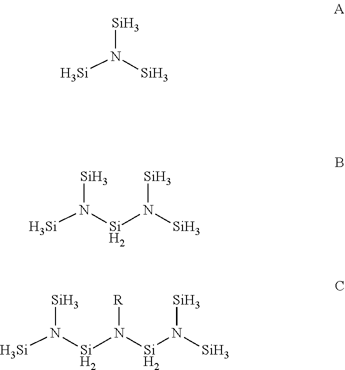

wherein R is selected from hydrogen, a linear C₁ to C₁₀ alkyl group, a branched C₃ to C₁₀ alkyl group, a C₃ to C₁₀ cyclic alkyl group, a C₃ to C₁₀ heterocyclic group, a C₃ to C₁₀ alkenyl group, a C₃ to C₁₀ alkynyl group, and a C₄ to C₁₀ aryl group.

In one aspect, there is provided a method of forming a multi-layered silicon nitride film via combination of (1) a plasma enhanced atomic layer deposition (PEALD) or a plasma enhanced cyclic chemical vapor deposition (PECCVD) and (2) a plasma enhanced chemical vapor deposition method (PECVD). According to this embodiment the multi-layered silicon nitride comprises a PEALD or PECCVD silicon nitride/PECVD silicon nitride/PEALD or PECCVD silicon nitride film. The method steps are next described.

(1): The PEALD or PECCVD method comprises:
a. providing a substrate in a reactor;
b. introducing into the reactor at least one silicon precursor comprising at least three Si—N bonds and at least three SiH₃ groups represented by structures below:

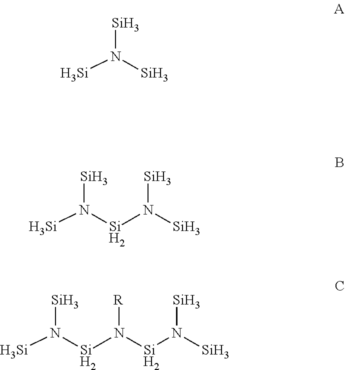

wherein R is selected from hydrogen, a linear C₁ to C₁₀ alkyl group, a branched C₃ to C₁₀ alkyl group, a C₃ to C₁₀ cyclic alkyl group, a C₃ to C₁₀ heterocyclic group, a C₃ to C₁₀ alkenyl group, a C₃ to C₁₀ alkynyl group, and a C₄ to C₁₀ aryl group; and wherein the at least one silicon precursor reacts on at least a portion of the surface of the substrate to provide a chemisorbed layer;
c. purging the reactor with a purge gas;
d. introducing a plasma containing source into the reactor to react with at least a portion of the chemisorbed layer and provide at least one reactive site wherein the plasma is generated at a power density ranging from about 0.01 to about 1.5 W/cm²; and
e. optionally purging the reactor with an inert gas;
   wherein the steps b through e are repeated until a desired thickness of the silicon nitride film is obtained. A flow of argon, noble, and/or other inert gas may be employed as a carrier gas to help deliver the vapor of the at least one silicon precursor to the reaction chamber during the precursor pulsing. In certain embodiments, the reaction chamber process pressure is about 2 Torr or less. In other embodiments, the reaction chamber process pressure is about 10 Torr or less. In certain embodiments of the method, a plasma comprising hydrogen can be inserted before step d to help remove hydrocarbon generated from the reaction between the silicon and the surface. The plasma comprising hydrogen is selected from the group consisting of hydrogen plasma, hydrogen/helium, hydrogen/argon plasma, hydrogen/neon plasma and mixtures thereof. In some embodiments, the plasma containing source may be introduced into the reactor in the form of at least one nitrogen source and/or may be present incidentally in the other precursors used in the deposition process. Suitable nitrogen-containing source gases may include, for example, ammonia, hydrazine, monoalkylhydrazine, dialkylhydrazine, nitrogen plasma, nitrogen/hydrogen, nitrogen/helium, nitrogen/argon plasma, ammonia plasma, nitrogen/ammonia plasma, ammonia/helium plasma, ammonia/argon plasma, ammonia/nitrogen plasma, NF₃ plasma, organoamine plasma, and mixtures thereof. In other embodiments, the plasma is selected from the group consisting of hydrogen plasma, helium plasma, neon plasma, argon plasma, xenon plasma, hydrogen/helium plasma, hydrogen/argon plasma and mixtures thereof.

(2): The PECVD method comprises:
a. providing the substrate having silicon nitride prepared by PEALD in a reactor from Step (1);
b. introducing at least one silicon precursor comprising at least three Si—N bonds and at least three SiH₃ groups represented by structures below:

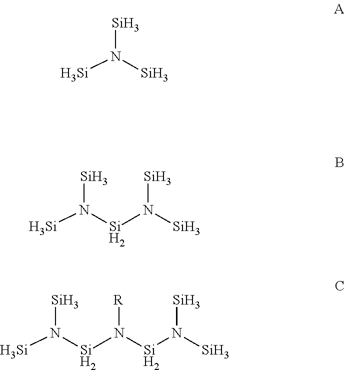

wherein R is selected from hydrogen, a linear C₁ to C₁₀ alkyl group, a branched C₃ to C₁₀ alkyl group, a C₃ to C₁₀ cyclic alkyl group, a C₃ to C₁₀ heterocyclic group, a C₃ to C₁₀ alkenyl group, a C₃ to C₁₀ alkynyl group, and a C₄ to C₁₀ aryl group; and a nitrogen source simultaneously into the reactor under direct plasma to form silicon nitride wherein the plasma is generated at a power density ranging from about 0.01 to about 1.5 W/cm². Suitable nitrogen-containing source gases may include, for example, ammonia, hydrazine, monoalkylhydrazine, dialkylhydrazine, nitrogen/hydrogen, nitrogen/helium, and mixtures thereof.

Step (3) The PEALD or PECCVD method comprises:
a. providing a substrate having silicon nitride prepared by PECVD from Step (2) in a reactor;
b. introducing into the reactor at least one silicon precursor comprising at least three Si—N bonds and at least three SiH₃ groups represented by structures below:

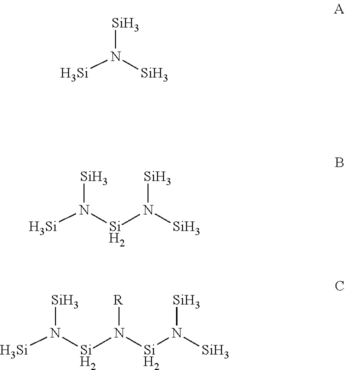

wherein R is selected from hydrogen, a linear C₁ to C₁₀ alkyl group, a branched C₃ to C₁₀ alkyl group, a C₃ to C₁₀ cyclic alkyl group, a C₃ to C₁₀ heterocyclic group, a C₃ to C₁₀ alkenyl group, a C₃ to C₁₀ alkynyl group, and a C₄ to C₁₀ aryl group; and wherein the at least one silicon precursor reacts on at least a portion of the surface of the substrate to provide a chemisorbed layer;
c. purging the reactor with a purge gas;
d. introducing a plasma containing source into the reactor to react with at least a portion of the chemisorbed layer and provide at least one reactive site wherein the plasma is generated at a power density ranging from about 0.01 to about 1.5 W/cm²; and
e. optionally purging the reactor with an inert gas;
   wherein the steps b through e are repeated until a desired thickness of the silicon nitride film is obtained

In another aspect, there is provided a method of forming a multi-layered silicon nitride film via combination of a plasma enhanced atomic layer deposition and a plasma enhanced cyclic chemical vapor deposition. The multi-layered silicon nitride comprises a PECVD silicon nitride/PEALD or PECCVD silicon nitride/PECVD silicon nitride film. The method comprises the steps (1) to (3) as below.

Step (1): The PECVD method comprises:
a. providing a substrate in a reactor; and
b. introducing at least one silicon precursor comprising at least three Si—N bonds and at least three SiH₃ groups represented by structures below:

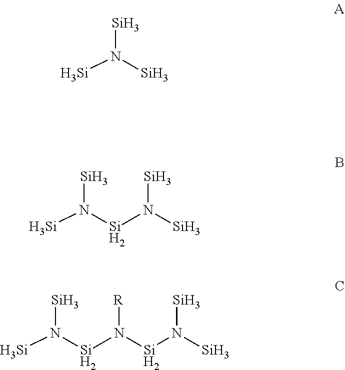

wherein R is selected from hydrogen, a linear C₁ to C₁₀ alkyl group, a branched C₃ to C₁₀ alkyl group, a C₃ to C₁₀ cyclic alkyl group, a C₃ to C₁₀ heterocyclic group, a C₃ to C₁₀ alkenyl group, a C₃ to C₁₀ alkynyl group, and a C₄ to C₁₀ aryl group; and a nitrogen source simultaneously into the reactor under direct plasma to form silicon nitride wherein the plasma is generated at a power density ranging from about 0.01 to about 1.5 W/cm². Suitable nitrogen-containing source gases may include, for example, ammonia, hydrazine, monoalkylhydrazine, dialkylhydrazine, nitrogen/hydrogen, nitrogen/helium, and mixtures thereof.

Step (2): The PEALD or PECCVD comprises:
a. providing a substrate having silicon nitride prepared by PECVD in a reactor from Step (1);
b. introducing into the reactor at least one silicon precursor comprising at least three Si—N bonds and at least three SiH₃ groups represented by structures below:

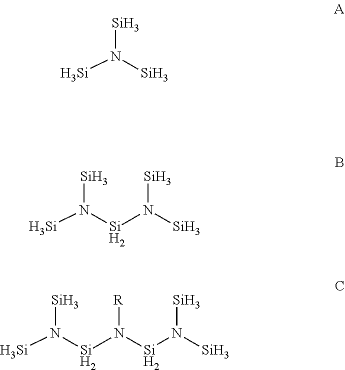

wherein R is selected from hydrogen, a linear C₁ to C₁₀ alkyl group, a branched C₃ to C₁₀ alkyl group, a C₃ to C₁₀ cyclic alkyl group, a C₃ to C₁₀ heterocyclic group, a C₃ to C₁₀ alkenyl group, a C₃ to C₁₀ alkynyl group, and a C₄ to C₁₀ aryl group; and wherein the at least one silicon precursor reacts on at least a portion of the surface of the substrate to provide a chemisorbed layer;
c. purging the reactor with a purge gas;
d. introducing a plasma containing source into the reactor to react with at least a portion of the chemisorbed layer and provide at least one reactive site wherein the plasma is generated at a power density ranging from about 0.01 to about 1.5 W/cm²; and
e. optionally purging the reactor with an inert gas;
   wherein the steps b through e are repeated until a desired thickness of the silicon nitride film is obtained. A flow of argon, noble, and/or other inert gas may be employed as a carrier gas to help deliver the vapor of the at least one silicon precursor to the reaction chamber during the precursor pulsing. In certain embodiments, the reaction chamber process pressure is about 2 Torr or less. In other embodiments, the reaction chamber process pressure is about 10 Torr or less. In certain embodiments of the method, a plasma comprising hydrogen can be inserted before step d to help remove hydrocarbon generated from the reaction between the silicon and the surface. The plasma comprising hydrogen is selected from the group consisting of hydrogen plasma, hydrogen/helium, hydrogen/argon plasma, hydrogen/neon plasma and mixtures thereof. In some embodiments, the plasma containing source may be introduced into the reactor in the form of at least one nitrogen source and/or may be present incidentally in the other precursors used in the deposition process. Suitable nitrogen-containing source gases may include, for example, ammonia, hydrazine, monoalkylhydrazine, dialkylhydrazine, nitrogen plasma, nitrogen/hydrogen, nitrogen/helium, nitrogen/argon plasma, ammonia plasma, nitrogen/ammonia plasma, ammonia/helium plasma, ammonia/argon plasma, ammonia/nitrogen plasma, NF₃ plasma, organoamine plasma, and mixtures thereof. In other embodiments, the plasma is selected from the group consisting of hydrogen plasma, helium plasma, neon plasma, argon plasma, xenon plasma, hydrogen/helium plasma, hydrogen/argon plasma and mixtures thereof.

Step (3) The PECVD method comprises:
a. providing a substrate having silicon nitride prepared by PEALD or PECCVD from Step (2) in a reactor;
b. introducing at least one silicon precursor comprising at least three Si—N bonds and at least three SiH₃ groups represented by structures below:

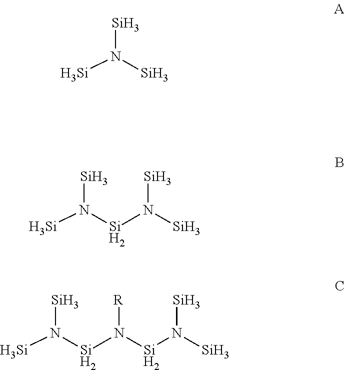

wherein R is selected from hydrogen, a linear C₁ to C₁₀ alkyl group, a branched C₃ to C₁₀ alkyl group, a C₃ to C₁₀ cyclic alkyl group, a C₃ to C₁₀ heterocyclic group, a C₃ to C₁₀ alkenyl group, a C₃ to C₁₀ alkynyl group, and a C₄ to C₁₀ aryl group; and a nitrogen source simultaneously into the reactor under direct plasma to form silicon nitride wherein the plasma is generated at a power density ranging from about 0.01 to about 1.5 W/cm². Suitable nitrogen-containing source gases may include, for example, ammonia, hydrazine, monoalkylhydrazine, dialkylhydrazine, nitrogen/hydrogen, nitrogen/helium, and mixtures thereof.

The thickness of PEALD silicon nitride in this invention is about 20 to 400 Å, about 20 to 200 Å, or about 40 to 200 Å, or about 50 to 200 Å, or about 50 to 150 Å, or about 80 to 200 Å, or about 100 to 200 Å. The thickness of PECVD silicon nitride in this invention is about 200 to 10000 Å, about 200 to 1000 Å, or about 300 to 1000 Å, or about 400 to 1000 Å, or about 500 to 1000 Å, or about 600 to 1000 Å. The total thickness of multi-layered silicon nitride is about 400 to 30000 Å, about 400 to 10000 Å, about 400 to 8000 Å, about 400 to about 7000 Å, about 400 to about 6000 Å, about 400 to about 5000 Å, about 400 to 2500 Å, or about 400 to 2400 Å, or about 400 to 2200 Å, or about 400 to 2000 Å, about 400 to 1000 Å, or about 400 to 900 Å, or about 400 to 700 Å.

It is believed that combination of PEALD and PECVD process could provide a better gas barrier as PEALD or PECCVD could help seal any micro-holes or cracks generated from PECVD silicon nitride.

In certain embodiments, the method disclosed herein avoids pre-reaction of precursor(s) by using ALD or CCVD methods that separate the precursor(s) prior to and/or during the introduction to the reactor. In this connection, deposition techniques such as ALD or CCVD processes are used to deposit the silicon-containing film. In one embodiment, the film is deposited via a combination of a PEALD process and a PECVD in a typical single wafer ALD reactor, semi-batch ALD reactor, or batch furnace ALD reactor. In another embodiment, the film is deposited via combination of a PEALD process and a PECVD in a typical cluster tool comprising a PEALD reactor and a PECVD reactor. In another embodiment, each reactant including the silicon precursor and reactive gas is exposed to a substrate by moving or rotating the substrate to different sections of the reactor and each section is separated by inert gas curtain, i.e. spatial ALD reactor or roll to roll ALD reactor.

While not being bound by theory, it is believed that the silicon precursor compounds having three or more Si—N bonds, and optionally three or more Si—H₃ groups, in Formulae A to C are more reactive towards at least a portion of the substrate surface, thus anchoring more silicon fragments on the surface during the deposition process. This in turn will increase the growth rate of the film as well as provide better surface coverage for substrate comprising surface features, such as without limitation, pores, trenches, and/or vias, thereby allowing for the deposition of a conformal silicon nitride or other silicon-containing film on the surface. An example of a Formulae A to C compound is bis(disilylamino)silane (aka N,N′-disilyltrisilazane). An example of a Formula IIC compound is tris (ethylsillyl) amine. In embodiments wherein the silicon precursor compound is tris(ethylsillyl)amine, it is believed that the ethylene acts as leaving group in the deposition process thereby creating additional Si reactive sites while at the same time lowering the Si—H content in the precursor.

As mentioned previously, the method used to form the silicon-containing materials and films described herein utilizes a combination of deposition processes. Examples of suitable deposition processes for the method disclosed herein include, but are not limited to, plasma enhanced ALD (PEALD) or plasma enhanced cyclic CVD (PECCVD) process. As used herein, the term “chemical vapor deposition processes” refers to any process wherein a substrate is exposed to one or more volatile precursors, which react and/or decompose on the substrate surface to produce the desired deposition. As used herein, the term “atomic layer deposition process” refers to a self-limiting (e.g., the amount of film material deposited in each reaction cycle is constant), sequential surface chemistry that deposits silicon containing films of materials onto substrates of varying compositions. Although the precursors, reagents and sources used herein may be sometimes described as “gaseous”, it is understood that the precursors can be either liquid or solid which are transported with or without an inert gas into the reactor via direct vaporization, bubbling or sublimation. In some case, the vaporized precursors can pass through a plasma generator. In one embodiment, the silicon nitride film is deposited using a plasma enhanced ALD process. In another embodiment, the silicon nitride film is deposited using a plasma enhanced CCVD process. The term “reactor” as used herein, includes without limitation, reaction chamber or deposition chamber. The ALD-like or PECCVD process is defined herein as a cyclic CVD process that provides a high conformal silicon nitride film such as, silicon nitride or silicon carbonitride on a substrate as shown by having at least one of the following: percentage of non-uniformity of about 5% or less as measured by ellipsometer, a deposition rate of 1 Å or greater per cycle, or a combination thereof.

The silicon precursor compounds having Formulae A to C may be delivered to the reaction chamber such as a PEALD or PECVD reactor in a variety of ways. In one embodiment, a liquid delivery system may be utilized. In an alternative embodiment, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor. In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

In one embodiment of the method described herein, a substrate having a surface to which at least a portion of silicon-containing film or materials is deposited thereupon, is placed into a reactor deposition chamber. The temperature of the substrate may be controlled to be less than the walls of the reactor. The substrate temperature is held at a temperature from about room temperature (e.g., 20° C.) to about 500° C. Alternative ranges for the substrate temperature have one or more of the following end points: 20, 50, 75, 80, 90, 100, 125, 150, 175, 200, 225, 250, 275, 300, 325, 350, 375, 400, 425, 450, 475, and 500° C. Exemplary temperature ranges include the following: 20 to 475° C., 100 to 400° C. or 175 to 350° C. Exemplary lower temperature ranges include 20 to 200° C., 20 to 100° C., 20 to 90° C., and 20 to 80° C. In some embodiments, the substrate temperatures for PEALD or PECVD are same. In other embodiments, the substrate temperatures for PEALD or PECVD can be different. In some embodiments, the PEALD or PECVD processes are performed in the same deposition chamber. In other embodiments, the PEALD or PECVD processes can be conducted in different deposition chambers.

Depending upon the deposition method, in certain embodiments, the one or more silicon-containing precursor compounds may be introduced into the reactor at a predetermined molar volume, or from about 0.1 to about 1000 micromoles. In this or other embodiments, the silicon precursor or the silicon precursor comprising Formula A to C and a solvent may be introduced into the reactor for a predetermined time period. In certain embodiments, the time period ranges from about 0.001 to about 500 seconds for either the PEALD/PECCVD or the PECVD depositions, although they can be performed at the same or different temperatures.

The multi-layered silicon-containing films deposited using the methods described herein are formed in the presence of nitrogen-containing source. A nitrogen-containing source may be introduced into the reactor in the form of at least one nitrogen-containing source and/or may be present incidentally in the other precursors used in the deposition process. Suitable nitrogen-containing source gases may include, for example, ammonia, hydrazine, monoalkylhydrazine, dialkylhydrazine, plasma comprising nitrogen, plasma comprising nitrogen and hydrogen, plasma comprising nitrogen and helium, plasma comprising nitrogen and argon, ammonia plasma, plasma comprising nitrogen and ammonia, plasma comprising ammonia and helium, plasma comprising ammonia and argon plasma, NF₃ plasma, organoamine plasma, and mixtures thereof. In other embodiments, the plasma is selected from the group consisting of hydrogen plasma, helium plasma, neon plasma, argon plasma, xenon plasma, hydrogen/helium plasma, hydrogen/argon plasma and mixtures thereof. In one particle embodiment, the nitrogen containing source is substantially free of (e.g., has 2 weight percent (wt. %) or less) hydrogen to avoid introducing additional hydrogen into the final silicon nitride film and is selected from the group consisting of nitrogen plasma, nitrogen/helium, nitrogen/argon plasma. In another embodiment, the nitrogen containing source is selected from monoalkylhydrazine, dialkylhydrazine. For deposition of silicon carbonitride, the nitrogen containing source can be selected from the group consisting of organic amine plasma such as methylamine plasma, dimethylamine plasma, trimethylamine plasma, ethylamine plasma, diethylamine plasma, trimethylamine plasma, ethylenediamine plasma. Throughout the description, the term “organic amine” as used herein describes organic compound has at least one nitrogen atom. Examples of organic amine, but are not limited to, methylamine, ethylamine, propylamine, iso-propylamine, tert-butylamine, sec-butylamine, tert-amylamine, ethylenediamine, dimethylamine, trimethylamine, diethylamine, pyrrole, 2,6-dimethylpiperidine, di-n-propylamine, di-iso-propylamine, ethylmethylamine, N-methylaniline, pyridine, triethylamine. Similarly, throughout the description, the term “organoamino group” as used herein refers to an organic group consisting of at least one nitrogen atom derived from secondary or primary organoamines as described above. “Organoamino group” does not include —NH₂ group. In some embodiments, the plasma is generated in situ while in other embodiments, the plasma can be provided remotely via a plasma generator.

In certain embodiments, the nitrogen-containing source is introduced into the reactor at a flow rate ranging from about 1 to about 2000 square cubic centimeters (sccm) or from about 1 to about 1000 sccm. The nitrogen-containing source can be introduced for a time that ranges from about 0.1 to about 100 seconds. In embodiments wherein the film is deposited by an ALD or a cyclic CVD process, the precursor pulse can have a pulse duration that is greater than 0.01 seconds, and the nitrogen-containing source can have a pulse duration that is less than 0.01 seconds. In yet another embodiment, the purge duration between the pulses that can be as low as 0 seconds or is continuously pulsed without a purge in-between.

In certain embodiments, the temperature of the reactor in the introducing step is at one or more temperatures ranging from about room temperature (e.g., 20° C.) to about 500° C. Alternative ranges for the substrate temperature have one or more of the following end points: 20, 50, 75, 100, 125, 150, 175, 200, 225, 250, 275, 300, 325, 350, 375, 400, 425, 450, 475, and 500° C. Exemplary preferred temperature ranges include the following: 20 to 200° C., 20 to 100° C., 20 to 90° C., and 20 to 80° C.

Energy is applied to the at least one precursor compound, nitrogen-containing source, oxygen-containing source, other reagents, or a combination thereof to induce reaction and to form the silicon-containing film or coating or a chemisorbed layer on at least a portion of the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively a remote plasma-generated process in which plasma is generated outside of the reactor and supplied into the reactor. In certain embodiments of the method described herein, the plasma is generated in situ at a power density ranging from about 0.01 to about 1.5 W/cm².

The deposition methods disclosed herein may involve one or more purge gases. The purge gas, which is used to purge away unconsumed reactants and/or reaction byproducts, is an inert gas that does not react with the precursors. Exemplary purge gases include, but are not limited to, argon (Ar), nitrogen (N₂), helium (He), neon, hydrogen (H₂), and mixtures thereof. In certain embodiments, a purge gas is supplied into the reactor at a flow rate ranging from about 10 to about 2000 sccm for about 0.1 to 1000 seconds, thereby purging the unreacted material and any byproduct that may remain in the reactor.

The respective step of supplying the precursors, oxygen-containing source, the nitrogen-containing source, and/or other precursors, source gases, and/or reagents may be performed by changing the time for supplying them to change the stoichiometric composition of the resultant film or material. A flow of argon and/or other gas may be employed as a carrier gas to help deliver the vapor of the at least one precursor compound to the reaction chamber during the precursor pulsing. In certain embodiments, the reaction chamber process pressure is about 10 Torr or less, 5 Torr or less, 2 Torr or less, 1 torr or less.

In one embodiment of the PEALD or PECCVD together with PECVD method described herein, a substrate is heated on a heater stage in a reaction chamber that is exposed to the precursor compound initially to allow the compound to chemically adsorb onto the surface of the substrate. A purge gas such as nitrogen, argon, or other inert gas purges away unabsorbed excess precursor compound from the process chamber. After sufficient purging, a nitrogen-containing source may be introduced into reaction chamber to react with the absorbed surface followed by another gas purge to remove reaction by-products from the chamber. The process cycle can be repeated to achieve the desired film thickness. In other embodiments, pumping under vacuum can be used to remove unabsorbed excess precursor compound from the process chamber, after sufficient evacuation under pumping, a nitrogen-containing source may be introduced into reaction chamber to react with the absorbed surface followed by another pumping down purge to remove reaction by-products from the chamber. In yet another embodiment, the precursor compound and the nitrogen-containing source can be co-flowed into reaction chamber to react on the substrate surface to deposit silicon nitride. In a certain embodiment of cyclic CVD, the purge step is not used.

In this or other embodiments, it is understood that the steps of the methods described herein may be performed in a variety of orders, may be performed sequentially or concurrently (e.g., during at least a portion of another step), and any combination thereof. The respective step of supplying the precursors and the nitrogen-containing source gases may be performed by varying the duration of the time for supplying them to change the stoichiometric composition of the resulting silicon-containing film.

The silicon precursors described herein and compositions comprising the silicon precursors having three or more Si—N bonds, and optionally three or more Si—H₃ groups represented by Formulae A to C, according to the present invention are preferably substantially free of halide ions such as chloride or metal ions such as Al. As used herein, the term “substantially free” as it relates to halide ions (or halides) such as, for example, chlorides and fluorides, bromides, iodides, Al³⁺ ions, Fe²⁺, Fe³⁺, Ni²⁺, Cr³⁺ means less than 5 ppm (by weight), preferably less than 3 ppm, and more preferably less than 1 ppm, and most preferably 0 ppm. Chlorides or metal ions are known to act as decomposition catalysts for silicon precursors. Significant levels of chloride in the final product can cause the silicon precursors to degrade. The gradual degradation of the silicon precursors may directly impact the film deposition process making it difficult for the semiconductor manufacturer to meet film specifications. In addition, the shelf-life or stability is negatively impacted by the higher degradation rate of the silicon precursors thereby making it difficult to guarantee a 1-2 year shelf-life.

Compositions according to the present invention that are substantially free of halides can be achieved by (1) reducing or eliminating chloride sources during chemical synthesis, and/or (2) implementing an effective purification process to remove chloride from the crude product such that the final purified product is substantially free of chlorides. Chloride sources may be reduced during synthesis by using reagents that do not contain halides such as chlorodislanes, bromodisilanes, or iododislanes thereby avoiding the production of by-products that contain halide ions. In addition, the aforementioned reagents should be substantially free of chloride impurities such that the resulting crude product is substantially free of chloride impurities. In a similar manner, the synthesis should not use halide-based solvents, catalysts, or solvents which contain unacceptably high levels of halide contamination. The crude product may also be treated by various purification methods to render the final product substantially free of halides such as chlorides. Such methods are well described in the prior art and, may include, but are not limited to purification processes such as distillation, or adsorption. Distillation is commonly used to separate impurities from the desire product by exploiting differences in boiling point. Adsorption may also be used to take advantage of the differential adsorptive properties of the components to effect separation such that the final product is substantially free of halide. Adsorbents such as, for example, commercially available MgO—Al₂O₃ blends can be used to remove halides such as chloride.

For those embodiments relating to a composition comprising a solvent(s) and a silicon precursor having Formulae A to C described herein, the solvent or mixture thereof selected does not react with the silicon precursors. The amount of solvent by weight percentage in the composition ranges from 0.5% by weight to 99.5% or from 10% by weight to 75%. In this or other embodiments, the solvent has a boiling point (b.p.) similar to the b.p. of the silicon precursor precursors of Formulae A to C or the difference between the b.p. of the solvent and the b.p. of the silicon precursor precursors of Formulae A to C is 40° C. or less, 30° C. or less, or 20° C. or less, 10° C. or less, or 5° C. or less. Alternatively, the difference between the boiling points ranges from any one or more of the following end-points: 0, 10, 20, 30, or 40° C. Examples of suitable ranges of b.p. difference include without limitation, 0 to 40° C., 20° to 30° C., or 10° to 30° C. Examples of suitable solvents in the compositions include, but are not limited to, an ether (such as 1,4-dioxane, dibutyl ether), a tertiary amine (such as pyridine, 1-methylpiperidine, 1-ethylpiperidine, N,N′-Dimethylpiperazine, N,N,N′,N′-Tetramethylethylenediamine), a nitrile (such as benzonitrile), an alkyl hydrocarbon (such as octane, nonane, dodecane, ethylcyclohexane), an aromatic hydrocarbon (such as toluene, mesitylene), a tertiary aminoether (such as bis(2-dimethylaminoethyl) ether), or mixtures thereof. Some non-limiting exemplary compositions include, but are not limited to, a composition comprising bis(disilylamino)silane (b.p. about 135° C.) and octane (b.p. 125 to 126° C.); a composition comprising bis(disilylamino)silane (b.p. about 135° C.) and ethylcyclohexane (b.p. 130-132° C.); a composition comprising bis(disilylamino)silane (b.p. about 135° C.) and cyclooctane (b.p. 149° C.); a composition comprising bis(disilylamino)silane (b.p. about 135° C.), and toluene (b.p. 115° C.).

As mentioned previously, the method described herein may be used to deposit a silicon nitride film on at least a portion of a substrate. Examples of suitable substrates include but are not limited to, silicon, SiO₂, Si₃N₄, OSG, FSG, silicon carbide, hydrogenated silicon carbide, silicon nitride, hydrogenated silicon nitride, silicon carbonitride, hydrogenated silicon carbonitride, boronitride, antireflective coatings, photoresists, a flexible substrate such as IGZO, organic polymers, porous organic and inorganic materials, metals such as copper and aluminum, and diffusion barrier layers such as but not limited to TiN, Ti(C)N, TaN, Ta(C)N, Ta, W, or WN. The films are compatible with a variety of subsequent processing steps such as, for example, chemical mechanical planarization (CMP) and anisotropic etching processes.

The deposited films have applications, which include, but are not limited to, computer chips, optical devices, magnetic information storages, coatings on a supporting material or substrate, microelectromechanical systems (MEMS), nanoelectromechanical systems, thin film transistor (TFT), light emitting diodes (LED), organic light emitting diodes (OLED), IGZO, and liquid crystal displays (LCD).

The following examples illustrate the method for depositing silicon-containing materials or films described herein and are not intended to limit it in any way.

### Working Examples

In the following examples, unless stated otherwise, properties were obtained from sample films that were deposited onto medium resistivity (1-10 Ω-cm, p-type) single crystal silicon wafer substrates. All film depositions were performed using the CN-1 reactor, which has showerhead design, with 13.56 MHz direct plasma or the cross flow type CN-1 reactor without plasma (for comparative examples). In typical process conditions, unless stated otherwise, the chamber pressure was fixed at a pressure ranging from about 1 to about 5 Torr. Additional inert gas was used to maintain chamber pressure. The silicon precursor was delivered using vapor draw (i.e. no argon used at all). Typical RF power used was 125 W over electrode area of 200 mm wafer to provide a power density of 0.7 W/cm². The film depositions comprised the steps listed in Table 1 and 2 for PEALD and PECVD, respectively. Steps 1 through 4 in Table 1 constitute one PEALD cycle and were repeated, unless otherwise specified, a total of 300 times to get the desired film thickness.

TABLE 1
Steps used in PEALD silicon nitride films

| Step | |
|---|---|
| 1 | Introduce a silicon precursor to the reactor; additional |
| | inert gas is used to maintain chamber pressure to provide |
| | a chemisorbed layer |
| 2 | Purge the silicon precursor from the reactor chamber |
| | with inert gas |
| 3 | Activate a plasma to react with the surface of the |
| | chemisorbed layer and create reactive sites |
| 4 | Purge unreacted plasma species out |

TABLE 2
Conditions used in PECVD silicon nitride films

| Step | |
|---|---|
| 1 | Introduce a silicon precursor and a nitrogen-containing source |
| | simultaneously into the reactor while activating plasma; |
| | additional inert gas is used to maintain chamber pressure |

The reactive index (RI) and thickness for the deposited films were measured using an ellipsometer. Film non-uniformity was calculated using the standard equation: % non uniformity=((max thickness−min thickness)/(2*average (avg) thickness)). Film structure and composition were analyzed using Fourier Transform Infrared (FTIR) spectroscopy and X-Ray Photoelectron Spectroscopy (XPS). The density for the films was measured with X-ray Reflectometry (XRR).

The water vapor transmission rate (WVTR) was measured using a Deltaperm tool. The Deltaperm uses the total pressure method for measuring the rate of permeation. Between the two sides of a test sample a pressure difference is created. This pressure difference is the driving force for permeation. The gas or vapor permeates along the pressure gradient. The permeation process consists of two basic steps: solution into the sample and diffusion through the sample. The pressure increase on the side of the lower pressure (downstream side) is detected by a pressure sensor. From the measured pressure increase per unit of time the computer program calculates the rate of permeation, which in the case of water vapor is frequently called WVTR. The unit of the WVTR is usually given in g/m²day. The oven temperature and relative humidity are usually used at fixed values.

### PEALD Conditions:

Substrate temperature 85° C., chamber pressure 1 Torr, 50˜300 W (main power=150 W), N2=1,000 sccm, Ar[CAN]=vapor draw for precursor A, Ar[MO]=100 sccm

### PECVD Conditions:

Substrate temperature: 85˜100° C., chamber pressure 1˜5 Torr (main pressure=2.5 Torr), 50˜300 W (main power=250 W), H2=1,000 sccm, NH3=10 sccm, Ar[CAN]=vapor draw for precursor A, Ar[MO]=100 sccm

TABLE 3
Summary of Deposition Conditions, Film Properties and WVTR Results

| Substrate | | | Pressure | Power | Thickness | RI | WVTR |
|---|---|---|---|---|---|---|---|
| Temp, ° C. | Co-reactant | Conditions | (Torr) | (W) | (Å) | value | (g/m² · day) |
| 85 | N2 PEALD | 0.5/20/10*/20 × | 1 Torr | 150 | 412 | 1.97 | 5.05E−03 |
| | | 740 cy | | | | | |
| 85 | N2 PEALD | 0.5/20/10*/20 × | 1 Torr | 50 | 467 | 1.95 | 7.80E−03 |
| | | 750 cy | | | | | |
| 95 | NH3/H2 PECVD | 85 sec | 2.5 Torr | 250 | 672 | 2.01 | 1.60E−03 |
| 85 | NH3/H2 PECVD | 260 sec | 2.5 Torr | 250 | 2100 | 2.00 | 5.65E−04 |
| 100 | NH3/H2 PECVD | 85 sec | 2.5 Torr | 250 | 670 | 2.00 | 1.56E−03 |
| 95 | N2 PEALD + NH3/H2 | 1/15/10*/15 × | 1 Torr/ | 150/250/150 | 703 | 2.06 | 4.00E−04 |
| | PECVD + N2 PEALD | 74 cy + 75 sec + | 2.5 Torr/ | | | | |
| | | 1/15/10*/15 × 74 cy | 1 Torr | | | | |
| 85 | N2 PEALD + NH3/H2 | 1.5/15/10*/15 × | 1 Torr/ | 150/250/150 | 1153 | 1.93 | 6.50E−04 |
| | PECVD + N2 PEALD | 30 cy + 115 sec + | 2.5 Torr/ | | | | |
| | | 1.5/15/10*/15 × | 1 Torr | | | | |
| | | 30 cy | | | | | |

As shown in Table 3, the resulting silicon nitride potentially has the following advantages over the prior art: (a) total thickness is 2500 Å or less, 2000 Å or less, 1500 Å or less, or 1000 Å or less; (b) better water transmission rate with WVTR value of 5.0×10⁻⁵ g/m²·day or less, 5.0×10⁻⁴ g/m²·day or less, or 5.0×10⁻³ g/m²·day or less; (c) more flexible than existing one layer or bi-layer gas barrier because a thinner silicon nitride can be employed to prevent gases such as oxygen and moisture from permeating through the gas barrier; (d) less pinholes as PEALD can potentially seal most of pinholes generated from PECVD process.

1. A method for depositing a multi-layered silicon nitride film using a combination of deposition methods, the method comprising:
a. placing the substrate into a first reactor;
b. depositing on at least a portion of a surface of a substrate a first silicon nitride film, a second silicon nitride film, and a third silicon nitride film, which together form the multi-layered silicon nitride film, in a sequence of deposition methods via alternating between (1) either plasma enhanced atomic layered deposition (PEALD) or plasma enhanced cyclic chemical vapor deposition (PECCVD), and (2) PECVD,
wherein the PEALD or PECCVD deposition method (1) comprises the following steps i to iv, which are repeated until a desired thickness of a silicon nitride layer is obtained:
i. introducing into the reactor at least one silicon precursor compound comprising at least three Si—N bonds and at least three SiH₃ groups represented by Formulae A to C: 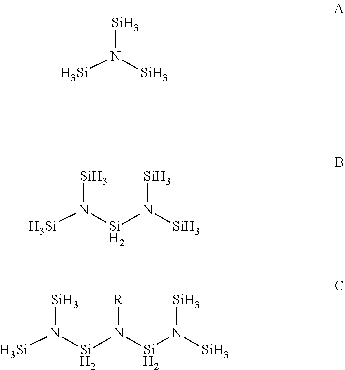
wherein substituent R is independently selected from a hydrogen, a linear C₁ to C₁₀ alkyl group; a branched C₃ to C₁₀ alkyl group; a linear or branched C₃ to C₁₂ alkenyl group; a linear or branched C₃ to C₁₂ alkenyl group; a linear or branched C₃ to C₁₂ alkynyl group; a C₄ to C₁₀ cyclic alkyl group; and a C₆ to C₁₀ aryl group under conditions sufficient to react on at least a portion of the surface to provide a chemisorbed layer;
ii. purging the reactor with a purge gas;
iii. introducing a first plasma containing source into the reactor to react with at least a portion of the chemisorbed layer and provide at least one reactive site wherein the plasma is generated at a power density ranging from about 0.01 to about 1.5 W/cm²; and
iv. optionally purging the reactor with an inert gas;
and wherein the PECVD deposition method (2) comprises the following step v:
v. introducing into the reactor an at least one silicon precursor represented by the structures A to C and a second plasma containing source to form silicon nitride, wherein the plasma is generated at a power density ranging from about 0.01 to about 1.5 W/cm²

2. The method of claim 1 wherein the first plasma containing source includes at least one gas selected from the group consisting of ammonia, hydrazine, monoalkylhydrazine, dialkylhydrazine, nitrogen, nitrogen/hydrogen, nitrogen/helium, nitrogen/argon, nitrogen/ammonia, ammonia/helium, ammonia/argon, ammonia/nitrogen, NF₃, organoamine, hydrogen, helium, neon, argon, xenon, hydrogen/helium, hydrogen/argon, and mixtures thereof.

3. The method of claim 1 wherein the second plasma containing source includes at least one gas selected from the group consisting of ammonia, hydrazine, monoalkylhydrazine, dialkylhydrazine, nitrogen/hydrogen, nitrogen/helium, and mixtures thereof.

4. The method of claim 1 wherein each silicon nitride film formed by PEALD or PECCVD has a thickness ranging between about 10 and about 200 Å.

5. The method of claim 1 wherein each silicon nitride film formed by PECVD has a thickness ranging between about 200 and about 1000 Å.

6. The method of claim 1 wherein the at least one silicon precursor compound comprises trisilylamine.

7. The method of claim 1 wherein the at least one silicon precursor compound comprises bis(disilylamino)silane (aka N,N′-disilyltrisilazane).

8. The method of claim 1 wherein the at least one silicon precursor compound comprises tris(ethylsillyl)amine.

9. The method of claim 1 wherein the substrate is held at temperatures ranging between about 20° C. and about 500° C. during deposition of the multi-layered silicon nitride film.

10. The method of claim 9 wherein the substrate is held at temperatures ranging between about 20° C. and about 100° C. during deposition of the multi-layered silicon nitride film.

11. The method of claim 1 wherein the multi-layered silicon nitride film has a water vapor transmission rate (WVTR) value of 5.0×10⁻⁵ g/m²·day or less.

12. The method of claim 1 wherein the multi-layered silicon nitride film has a WVTR value of 5.0×10⁻³ g/m²·day or less.

13. The method of claim 1 wherein the multi-layered silicon nitride film has a total thickness of up to 2500 Å.

14. The method of claim 1 wherein the multi-layered silicon nitride film has a total thickness of up to 1000 Å.

15. A multi-layered silicon nitride film formed by the method of claim 1.

16. A multi-layered silicon nitride film that has WVTR value of 5.0×10⁻³ g/m²·day or less.

17. The multi-layered silicon nitride film according to claim 16 that has a WVTR value of 5.0×10⁻⁵ g/m²·day or less.

18. The multi-layered silicon nitride film according to claim 16 that has a thickness of up to 10,500 Å.

19. The multi-layered silicon nitride film according to claim 15, which is employed as gas barrier layer for display devices.

20. The multi-layered silicon nitride film according to claim 15 that further has RI value of 1.90 or higher.

21. The method of claim 1, wherein the 1) PEALD or PECCVD and 2) PECVD methods are performed in the same deposition chamber.

22. The method of claim 1, wherein the 1) PEALD or PECCVD and 2) PECVD methods are performed in different deposition chambers.

23. The method of claim 1 wherein the first plasma is generated in situ.

24. The method of claim 1 wherein the first plasma is generated remotely.

25. The method of claim 1 wherein the first plasma is a combination of plasmas generated in situ and remotely.
